(19) United States
(12) Patent Application Publication
(10) Pub. No.: US 2023/0099939 A1
(43) Pub. Date: Mar. 30, 2023

(54) CONTROLLING THE THICKNESS AND WIDTH OF A CRYSTALLINE SHEET FORMED ON THE SURFACE OF A MELT USING COMBINED SURFACE COOLING AND MELT HEATING

(71) Applicant: LEADING EDGE EQUIPMENT TECHNOLOGIES, INC., Wilmington, MA (US)

(72) Inventors: Peter KELLERMAN, Essex, MA (US); Alison GREENLEE, Somerville, MA (US); Parthiv DAGGOLU, Danvers, MA (US); Alexander MARTINEZ, Woburn, MA (US); Nathan STODDARD, Chalfont, PA (US)

(21) Appl. No.: 17/801,181

(22) PCT Filed: Feb. 19, 2021
(86) PCT No.: PCT/US2021/018773

§ 371 Date: Aug. 19, 2022

Related U.S. Application Data
(60) Provisional application No. 62/978,536, filed on Feb. 19, 2020.

(51) Int. Cl. C30B 15/14; C30B 15/00; C30B 29/06; C30B 15/06; C30B 15/22

(52) U.S. Cl. CPC C30B 15/14; C30B 15/002; C30B 29/06; C30B 15/06; C30B 15/22

(57) ABSTRACT

An apparatus for controlling a thickness of a crystalline ribbon grown on a surface of a melt includes a crucible configured to hold a melt; a cold initializer facing an exposed surface of the melt; a segmented cooled thinning controller disposed above the crucible on a side of the crucible with the cold initializer; and a uniform melt-back heater disposed below of the crucible opposite the cooled thinning controller. Heat is applied to the ribbon through the melt using a uniform melt-back heater disposed below the melt. Cooling is applied to the ribbon using a segmented cooled thinning controller facing the crystalline ribbon above the melt.

### CROSS-REFERENCE TO RELATED APPLICATIONS

This application claims priority to the provisional patent application filed Feb. 19, 2020 and assigned U.S. App. No. 62/978,536, the disclosure of which is hereby incorporated by reference.

### STATEMENT REGARDING FEDERALLY-SPONSORED RESEARCH OR DEVELOPMENT

This invention was made with government support under Award Number DEEE0008132 awarded by the U.S. Department of Energy. The government has certain rights in the invention.

### FIELD OF THE DISCLOSURE

This disclosure relates to formation of crystalline sheets from a melt.

### BACKGROUND OF THE DISCLOSURE

Silicon wafers or sheets may be used in, for example, the integrated circuit or solar cell industry. Previously, cut silicon wafers were made by wire-sawing large silicon ingots or boules made from the Float-Zone (FZ) process, Czochralski (Cz) process, Modified Czochralski process (MCz) where magnetic fields are used to control oxygen, or a directional solidification (“cast”) process.

A single-step, continuous process that directly produces single crystal wafers from polysilicon feedstock is highly desirable. Continuous, direct wafer processes that produce net-shaped wafers eliminate many costly downstream process steps (like wire sawing) and can produce wafers with more uniform properties than discrete Cz ingot production. Unfortunately, historic direct silicon wafer processes have not been able to create the full-size single crystal silicon wafers. Specifically, vertical ribbon processes like Edge-Fed Growth and String Ribbon as well as horizontal substrate processes like Ribbon Growth on Substrate or Direct Wafer produce multicrystalline wafers. One vertical ribbon process known as Dendritic Web showed ability to make single crystal wafers, but the process could only yield narrow material (e.g., approximately 2 inches wide) before going unstable. Solar and semiconductor devices require larger wafers (>5 inches) for economic device manufacturing. Directly making single-crystal silicon wafers by epitaxially growing full-size silicon wafers on a porous silicon substrate that is then mechanically separated from the porous substrate also has been performed. Producing a wafer from epitaxial growth is expensive and subject to minority carrier lifetime (MCL)-limiting defects such as stacking faults and dislocations.

One promising method that has been investigated to lower the cost of materials for solar cells is the floating silicon method (FSM), which is a type of horizontal ribbon growth (HRG) technique where crystalline sheets are pulled horizontally along the surface of a melt. In this method, a portion of a melt surface is cooled sufficiently to locally initiate crystallization with the aid of a seed, which may be then drawn along the melt surface (while floating) to form a monocrystalline sheet. The local cooling may be accomplished by employing a device that rapidly removes heat above the region of the melt surface where crystallization is initiated. Under proper conditions, a stable leading edge of the crystalline sheet may be established in this region. Formation of a faceted leading edge is not obtained in Cz or other ribbon growth processes, and can add inherent stability to the growth interface.

In order to sustain the growth of this faceted leading edge in a steady-state condition with the growth speed matching the pull speed of the monocrystalline sheet or “ribbon,” intense cooling may be applied by a crystallizer in the crystallization region. This may result in the formation of a monocrystalline sheet whose initial thickness is commensurate with the width of the applied intensive cooling profile. The initial thickness is often on the order of 1-2 mm in the case of silicon ribbon growth. For applications such as forming solar cells from a monocrystalline sheet or ribbon, a target thickness may be on the order of 200 μm or less. This necessitates a reduction in thickness of the initially formed ribbon. This may be accomplished by heating the ribbon over a region of a crucible containing the melt as the ribbon is pulled in a pulling direction. As the ribbon is drawn through the region while the ribbon is in contact with the melt, a given thickness of the ribbon may melt back, thus reducing the ribbon thickness to a target thickness. This melt-back approach is particularly well suited in FSM, wherein a silicon sheet is formed floating on the surface of a silicon melt according to the procedures generally described above.

In FSM, a single-crystal sheet or ribbon is typically initialized with thickness>1 mm and total thickness variation (TTV)>100 μm. The ribbon floating on the melt provides opportunity to thin the ribbon before leaving the melt. A faceted leading edge may use intense gas jet cooling, as well as stabilization heat from the melt, resulting in ribbon thickness approximately equal to the width of the gas cooling profile at the surface of the melt, which is roughly Gaussian of width 1-2 mm (full width half maximum (FWHM)). Any small non-uniformity in gas jet and/or stabilization heat can result in a ribbon thickness non-uniformity up to 0.5 mm.

Previously, ribbon thinning was performed using a profiled (tuned) segmented melt-back heater (SMBH) below the crucible and melt. This provided greater melt-back heat to the thicker portions of the ribbon to obtain a uniformly thin ribbon. The resolution needed to melt back the ribbon to a uniform thinness over the full width of the ribbon can be approximately 1 cm. For solar wafers, the thickness may need to be <200 μm over a width of 156 mm with a TTV of <30 μm. A challenge with this method is that the melt is highly diffusive, spreading the heat from the segmented heater. The required resolution is maintained by reducing the depth of the melt to <5 mm. However, this depth is shallower than the depth needed to automatically wet-over quartz (>8 mm), and the process of wetting the melt such a shallow melt depth is challenging.

Another challenge is the melting behavior as the ribbon is thinned near the ribbon edge. The “thinning heat” diffuses to the melt at the side of the ribbon, causing the melt to super-heat, which causes the ribbon to narrow in its width. As the ribbon width narrows, more of this thinning heat results in further super-heating and further narrowing, thereby causing positive feedback (i.e., an instability), which can result in uncontrolled narrowing of the ribbon.

Embodiments of a SMBH are described in FIGS. 1A-1D and in U.S. Pat. No. 10,030,317, which is incorporated by reference in its entirety. FIG. 1A shows the geometry and ribbon narrowing using the SMBH. FIG. 1B shows how the melt-back heat thins the ribbon to a desired profile. FIG. 1C shows the required heat (per transverse length) needed to obtain the desired profile as a sum of individual SMBH Gaussian heat profiles. In FIG. 1C, Q is heat flux, x is linear position across the ribbon, Δt is the thickness change as a function of x, H_{f} is the latent heat of fusion, ρ is the mass density and Vₚᵤₗₗ is the linear pull speed, and hᵢ(x) is the profile function (e.g., Lorentzian or Gaussian) of the i-th element.

FIG. 1D shows the dependence of the individual heat profiles on melt depth, which includes the heat profile of FIG. 1C. Overlapping Gaussians or Lorentzian thermal profiles (parametrized conveniently using thermal finite element method models) describe the net melt-back heat as the ribbon traverses the length of the SMBH. The ribbon thickness profile measurement is done on the ribbon after it leaves the melt (e.g., optically). Heat flow from SMBH goes into ribbon melt-back thinning (latent heat) plus overflow on sides causing melt superheating and narrowing.

It is difficult to achieve the desired resolution (especially at the ribbon edge) without a shallow melt. However, using a shallow melt can create challenges of wetting the quartz surfaces of the crucible. Improved techniques to form thin and wide ribbons or wafers are needed.

### BRIEF SUMMARY OF THE DISCLOSURE

An apparatus for controlling a thickness of a crystalline ribbon grown on a surface of a melt is provided in a first embodiment. The apparatus includes a crucible configured to hold a melt, a cold initializer facing an exposed surface of the melt, a segmented cooled thinning controller disposed above the crucible on a side of the crucible with the cold initializer, and a uniform melt-back heater disposed below of the crucible opposite the cooled thinning controller. The segmented cooled thinning controller is configured to cool a surface of the melt. The uniform melt-back heater is configured to uniform heat to the melt.

The apparatus can include two insulating diffusion barriers disposed on the crucible between the cool thinning controller and the uniform melt-back heater. The insulating diffusion barriers are disposed in the melt on opposite sides of a ribbon formed on the melt.

The cooled thinning controller can include a plurality of gas jets. The cooled thinning controller also can include a cold block and a plurality of heaters, which can include one or more heat shields between the heaters.

The crucible can have a depth of 0.5 cm or more.

The apparatus can further include a puller configured to pull a ribbon formed on a surface of the melt in the crucible.

An insulating diffusion barrier can be disposed on the crucible between the cold initializer and the cooled thinning controller.

A method is provided in a second embodiment. The method includes providing a melt in a crucible. A ribbon floating on the melt is formed using a cold initializer facing an exposed surface of the melt. The ribbon is single crystal and the melt may include silicon. Heat can be applied to the ribbon through the melt using a uniform melt-back heater disposed below the melt. Cooling can be applied to the ribbon using a segmented cooled thinning controller facing the crystalline ribbon above the melt. The ribbon can be pulled. The ribbon is formed at a same rate as the pulling. The ribbon is separated from the melt at a wall of the crucible where a stable meniscus forms.

The method can further include minimizing diffusion of heat into an edge of the ribbon using two insulating diffusion barriers disposed in the melt.

The segmented cooled thinning controller can include a plurality of gas jets. The segmented cooled thinning controller also can include a cold block and a plurality of heaters, which can include one or more heat shields between the heaters.

The segments of the segmented cooled thinning controller and/or the uniform melt-back heater can be adjusted to provide a targeted thickness profile to the ribbon.

A thickness of the ribbon can be measured and dynamic feedback control of channels in the cooled thinning controller can be provided to maintain the thickness profile over an extended length of the ribbon.

### DESCRIPTION OF THE DRAWINGS

For a fuller understanding of the nature and objects of the disclosure, reference should be made to the following detailed description taken in conjunction with the accompanying drawings, in which:

FIGS. 1A-1D describes the an embodiment of an SMBH;

FIGS. 2A-2D illustrate an embodiment of a gas-cooled thinning controller (GCTC) in accordance with the present disclosure;

FIGS. 3A-3B illustrate GCTC versus SMBH spatial resolution;

FIG. 4 illustrates a representative thickness profile as a ribbon is pulled under the GCTC and over the uniform melt-back heater (UMBH);

FIG. 5 illustrates an exemplary system using insulating diffusion barriers;

FIG. 6 illustrates radiation cooling with a radiation-cooled thinning controller (RCTC);

FIG. 7 illustrates exemplary performance of the SMBH against the GCTC;

FIG. 8 illustrates an exemplary system using the UMBH and CTC; and

FIG. 9 is a flowchart of an exemplary method in accordance with the present disclosure.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

Although thinning a ribbon floating on the melt surface can be performed using heat from below, obtaining a uniform thickness can be accomplished by selectively thickening the thin portions of the ribbon using cooling from above (e.g., using a cooled thinning controller, or CTC). In an instance, the ribbon is cooled from above to thicken and melted uniformly from below. A combination of profiled (tuned) cooling from above and uniform heat from below (e.g., a single broad heater) can be used. In this way, the depth of the melt does not affect ribbon growth, because the resolution is obtained from above. A deep, flat-bottomed crucible can be used. There may be no diffusive medium above the melt to broaden this controlled cooling, so a high degree of resolution can be obtained without the previous issues of wetting over a shallow quartz crucible.

The CTC can be segmented. The segments can allow different cooling to be applied across a width of the ribbon. Thus, the cooling need not be uniform across a width of the ribbon. Individual gas jets or heaters across the width of the ribbon can be adjusted for ribbon growth.

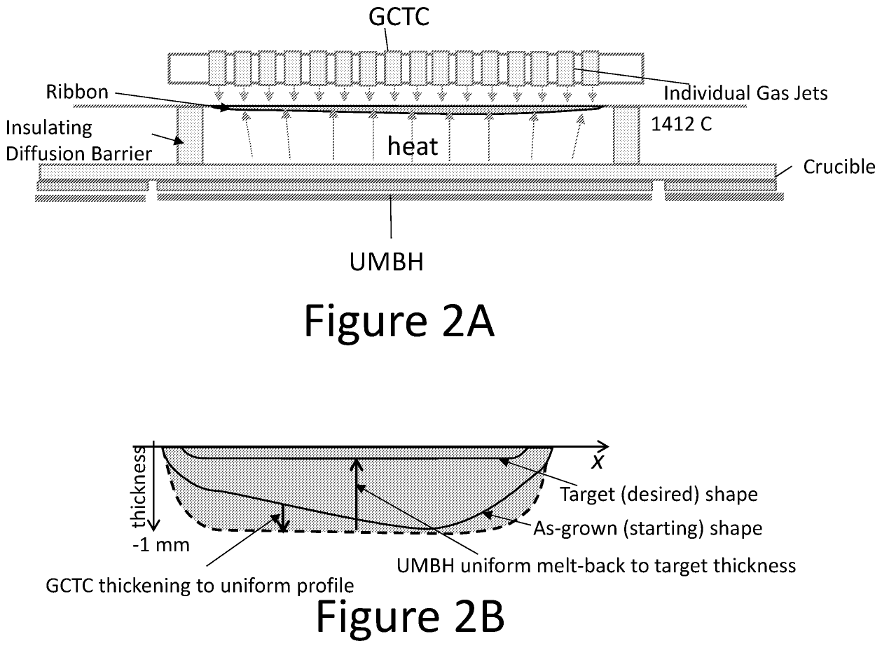

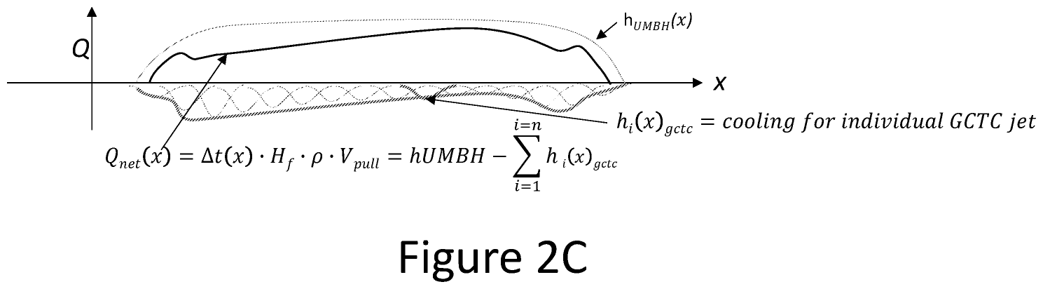

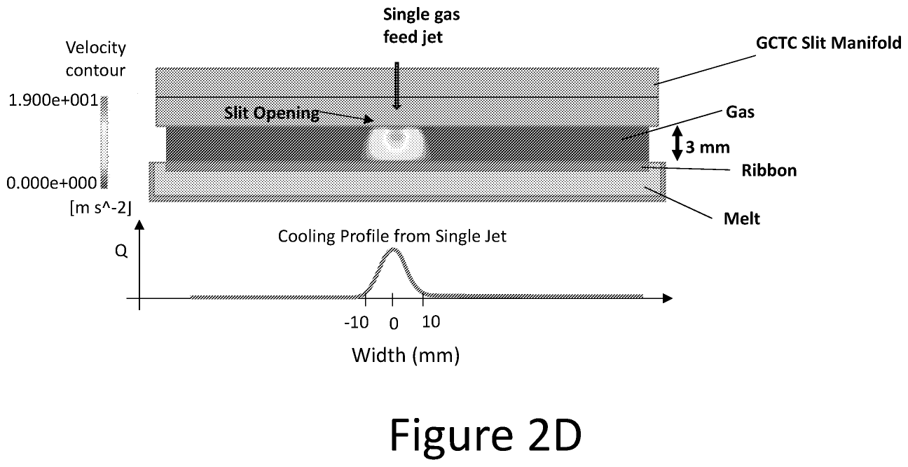

Excess melt-back heat at the edges can still cause uncontrolled and/or unstable narrowing of the ribbon. This can be mitigated by using insulating diffusion barriers (IDBs), such as quartz diffusion barriers (QDBs) in the crucible near the ribbon edges or a crucible of width beyond the ribbon's width to minimize the diffusion of heat into the ribbon edge. The IDBs may be blocks that extend from a floor of the crucible. In an instance, the IDBs are positioned beyond the ribbon edge to be proximate the ribbon edge at its desired width. This also improves the uniformity of the UMBH. As depicted in FIG. 2A and FIG. 4, the crucible holder has thermal breaks to help direct the heat flow to be vertical and uniform.

In an instance, an IDB has a width of approximately 5 mm and a height that can be approximately equal to a height of the melt. IDBs or crucible walls beyond an edge of the ribbon may be used unless it causes issues with melt freezing or ribbon attaching to quartz. The crucible and/or the IDBs may be fabricated of quartz.

FIG. 2A shows the geometry of a GCTC and UMBH. FIG. 2B shows how the combination of cooling (growth) plus melt-back heat thins the ribbon to a desired profile. FIG. 2C shows the exemplary requirements of heat/cooling per transverse length to obtain the desired profile as a sum of individual GCTC Gaussian cooling profiles plus UMBH heat profile. In FIG. 2C, h_{UMBH} is the heating profile of the UMBH (a heat flux profile as a function of x), and hᵢ(x)_{gctc} is the profile function of the GCTC cooling (shown as a negative curve).

The UMBH can have a single heater controlled with a single power control circuit. The UMBH can be configured to provide uniform melt-back heat into the melt. The UMBH may have approximately the same area opposite the crucible as the GCTC or RCTC.

FIG. 2D shows a computational fluid dynamics model of a cooling profile from a single jet in the GCTC. In FIG. 2D, GCTC resolution (i.e., the width of control cooling from each jet) is independent of melt depth and can be configured for correct width. There may be no diffusing medium between the GCTC and the ribbon.

In an embodiment, a combination of profiled (segmented) cooling from above and broad single heater heating from below is used to accomplish uniform thinning of a ribbon. One or more IDBs and/or a narrow crucible can be used to produce uniform melt-back heat and reduce the amount of ribbon narrowing.

As disclosed herein, the system and method can use a device that provides a modulated profile of gas cooling on the surface of the ribbon, referred to as the GCTC with a UMBH. A plurality of jets can be used together to provide a uniform and thin “knife” jet of controllable width (as disclosed in U.S. Pat. No. 9,957,636, which is incorporated by reference in its entirety), but also can be controlled to an arbitrary shape to achieve a wide and uniformly-thick ribbon. Thus, during operation, the various jets can be controlled to provide a desired net thickness profile. This arbitrary shape can have a particular minimum feature size or resolution. An example is shown in FIG. 2B. Narrowing of the ribbon can be controlled by increasing cooling in areas where narrowing would be occurring.

In an instance, the GCTC has from 4-32 jets across a width of a ribbon, which can be selected to adjust the ribbon thickness profile. For example, 16 jets can be used for a 16 cm width ribbon (i.e., 1 cm per jet). A gas flow from each gas jet of argon, nitrogen, helium, and/or hydrogen can be on the order of 0.1 to 3 standard liters per minute (SLM) per channel. Each gas jet can be a separate channel or multiple gas jets can be combined in a single channel. A gas temperature at the exit of the gas jet can be in a range from 300-600K. The gas jets can be positioned from 2-10 mm from a surface of the melt or the ribbon. The exit of the gas jet may be protected from SiO deposition by a purge gas.

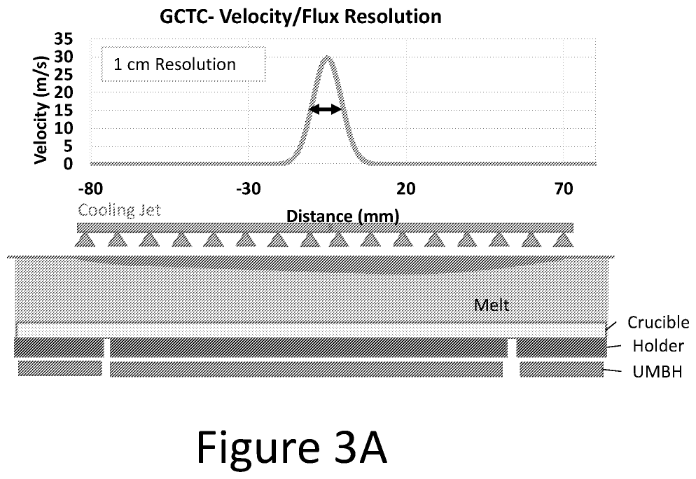

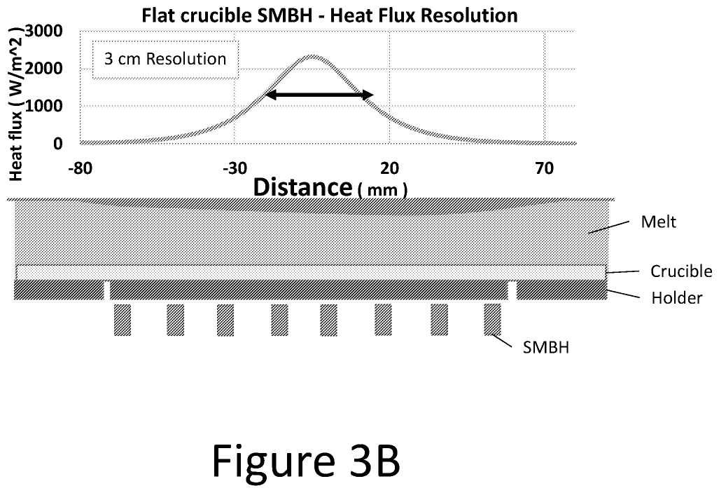

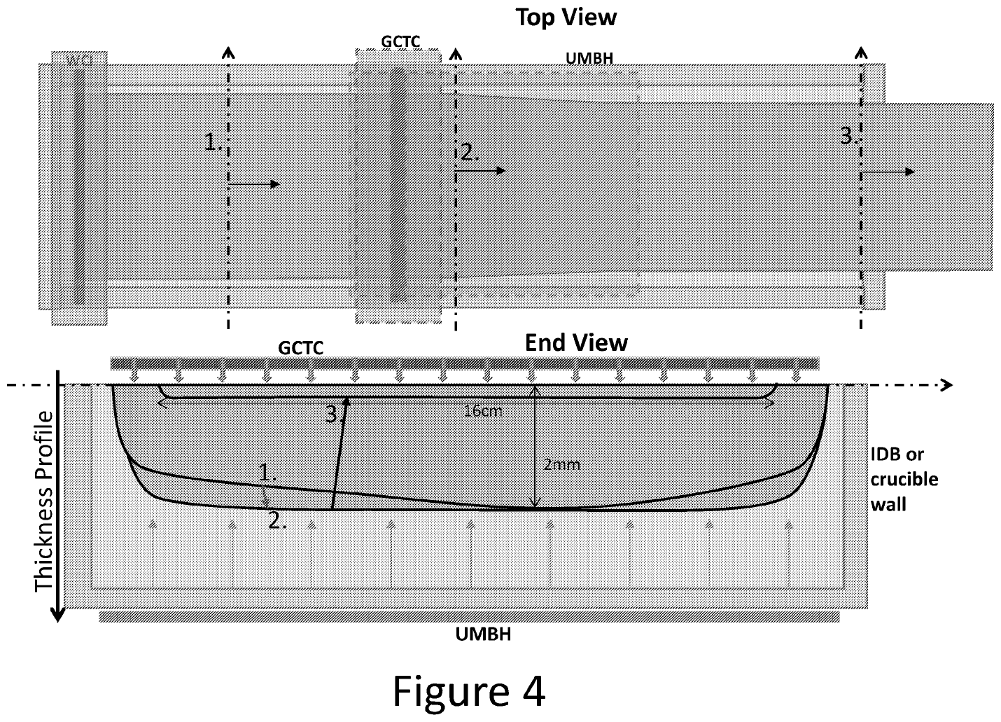

As shown in FIGS. 3A-3B, GCTC in a deep crucible (depth>1 cm) is capable of achieving better resolution than the SMBH approach in a crucible with depth<0.5 cm.

The process of combined modulated thickening to achieve uniform thickness and uniform thinning to achieve a thin, uniform ribbon is illustrated in FIG. 4. FIG. 4 depicts a thickness profile as a ribbon is pulled under the GCTC and over the UMBH using both a top view and end view. A point on the ribbon passes locations 1, 2, and 3. Location 1 is the starting thickness as initialized by a water-cooled initializer (WCI). Location 2 represents fast growth under the GCTC, which can be tuned for a uniform thickness. Location 3 is a uniform melt back from the UMBH.

The UMBH can be more effective and/or more uniform using IDBs within the crucible and/or using a crucible having a width just greater than that of the ribbon. Use of exemplary IDBs is described in U.S. Pat. No. 10,415,151, which is incorporated by reference in its entirety. In an instance, the IDB extends from the crucible approximately to the melt surface or beyond the melt surface.

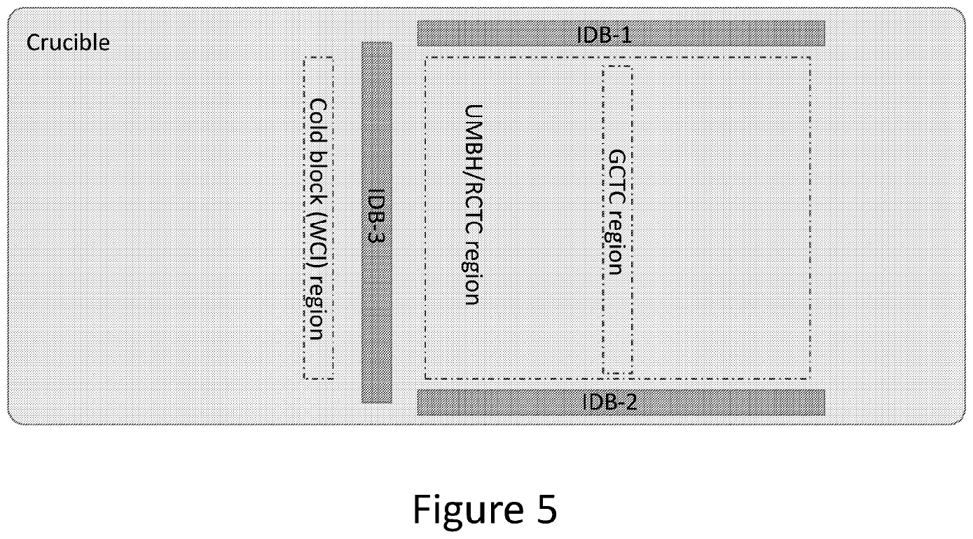

FIG. 5 illustrates exemplary IDBs in a crucible. In FIG. 5, IDB-1 and IDB-2 have a length along the long dimension of the crucible (i.e., a ribbon length) that is +/−10% a length of the UMBH. The IDB-1 and IDB-2 can have a width across the short dimension of the crucible (i.e., a ribbon width) from 5-20 mm and can be positioned at least 3 mm from an edge of the ribbon region. IDB-3 can have a width across the short dimension of the crucible from 5-20 mm. IDB-3 can have a length along the long dimension of the crucible that is +/−15 mm from the maximum ribbon dimension. The position of IDB-3 can be at least 5 mm from an edge of the WCI region.

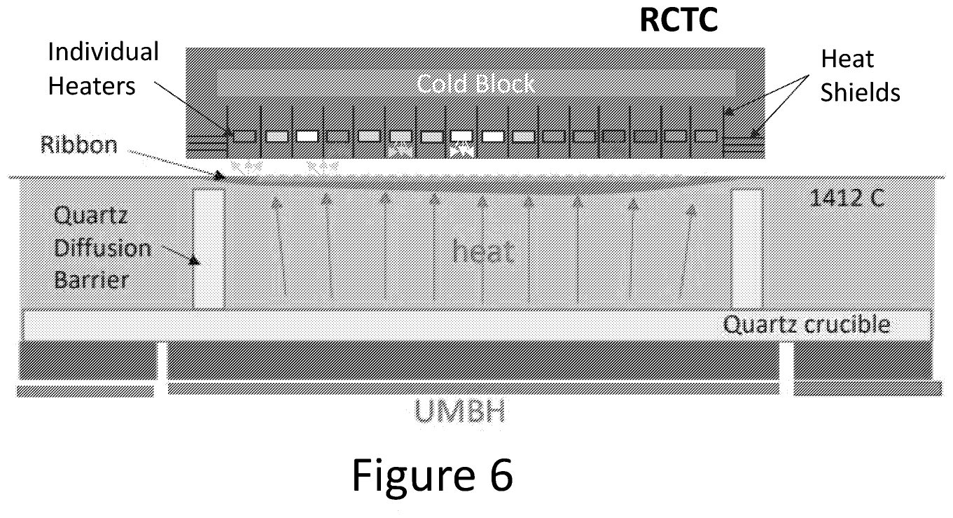

Radiation cooling is used in another embodiment, as shown in FIG. 6. The modulated cooling of the surface of the ribbon to achieve uniform thickness can use radiation cooling (e.g., the RCTC). Since the intensity of heat removal using radiation cooling is typically less that gas jet cooling, the RCTC may be greater than or equal to 10 cm in length (along the pull direction). For example, if the temperature of a channel or section of the RCTC is approximately 1250° C., the RCTC may need to be 15 cm long in order to locally thicken the ribbon by 500 μm. Using radiation cooling, individual cold profiles can be controlled by a balance between heaters and heat loss to a cold block. This can be configured to be less than 1 cm in width for an equivalent resolution as the GCTC. As shown in FIG. 6, all sections of the ribbon are radiating heat in all directions (two points are illustrated). The net melt-back in the ribbon is the difference between the heat provided from the UMBH and the net heat loss at the surface. The net heat loss at the surface is determined by the difference between the radiated heat from the ribbon surface (upwards pointing arrows from the ribbon to RCTC) and the compensating heat from the RCTC. In some cases, either the individual heater in a given channel is at a low power leading to maximum surface heat loss and minimum melt-back, or the individual channel heater is matching the surface heat loss, leading to maximum melt-back rate. In FIG. 6, channel heaters have different heater temperatures, with some being hotter and some being colder, which is represented by differences in shading. To maximize the spatial resolution of the RCTC, heat shields can be positioned between each heater channel, cutting down on the view factor of the ribbon surface and also reducing thermal mixing between adjacent heaters. Heat shields typically include of one or more layers of reflective material (e.g., a low emissivity, high melting point metal, such as tungsten, molybdenum, tantalum, iridium or platinum) and are maintained separated by an air gap from major heat sources or sinks. It can be noted that the shading of the heaters chosen in FIG. 6 are for illustrative purposes only and have not been chosen to address the particular wafer profile positioned below. In actual use, the hottest channels would operate above the thickest points in the ribbon and vice versa, controlled via feedback control. In practice, a bottom surface of the RCTC can be maintained at greater than 1250° C. so that SiO deposition is not a problem. The bottom surface of the RCTC also can be maintained below approximately 1425° C. (about 10 degrees above the melting point of silicon) in order to prevent melting of the top surface of the ribbon. A length of the RCTC along the pull direction can be configured to thicken the ribbon by 0.05 mm to 0.5 mm over, for example, a length of approximately 15 cm.

One benefit of the RCTC relative to the GCTC is that it can accomplish the melt-back without further thickening the wafer's low spots. The RCTC can operate by retarding the melt-back in the thicker positions instead of actively thickening the ribbon at points. Another benefit of the RCTC is that it roughly matches the UMBH in length, meaning that there is a more synchronistic behavior to the cooling. It can also be operated so as not to interfere with the seeding process, while the GCTC tends to have a thickening effect on the seed as it is proceeding into the furnace. Finally, the RCTC may be more compatible with the SiO containing furnace ambient and less likely to degrade or cause melt disturbances.

In an instance, the RCTC can include from 4-32 heaters across a width of the ribbon, such as 16 heaters for a 16 cm width ribbon (i.e., 1 heater/cm). The heaters may be positioned from 3-10 mm above the melt or ribbon. The heaters can be raised or lowered in a vertical direction relative to a surface of the melt or ribbon using an actuator. Heater power can be regulated in feedback, such as 50-300 W/channel. Each heater may be a separate channel or multiple heaters can be combined in a single channel.

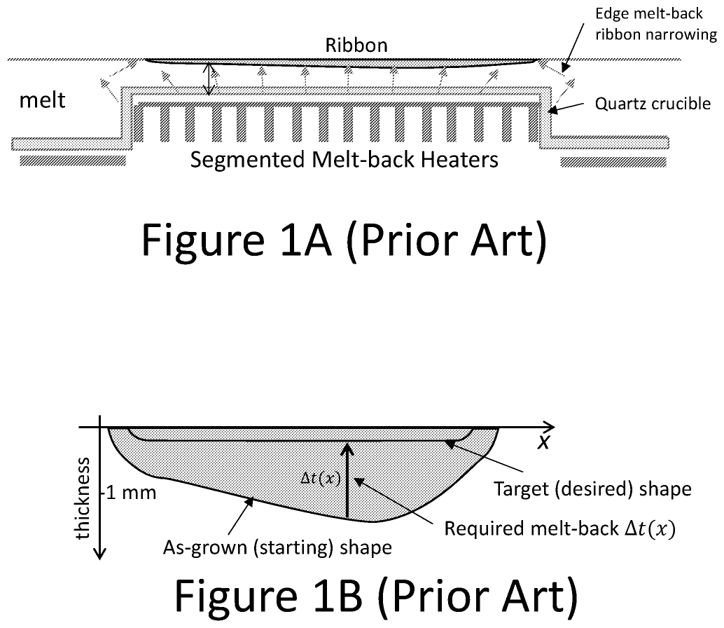

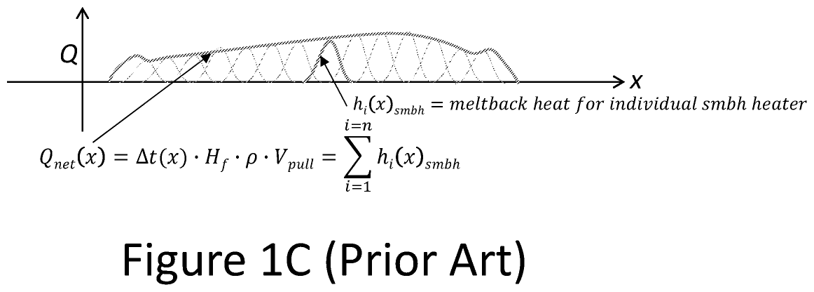

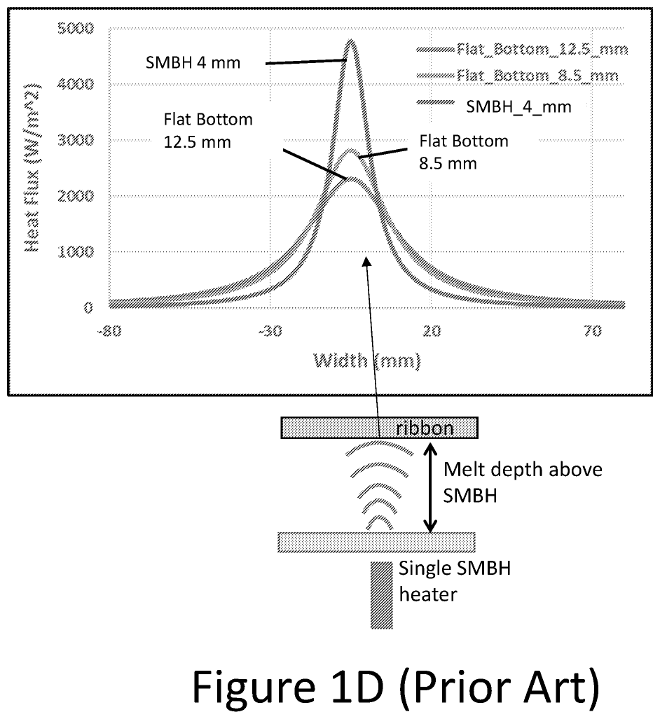

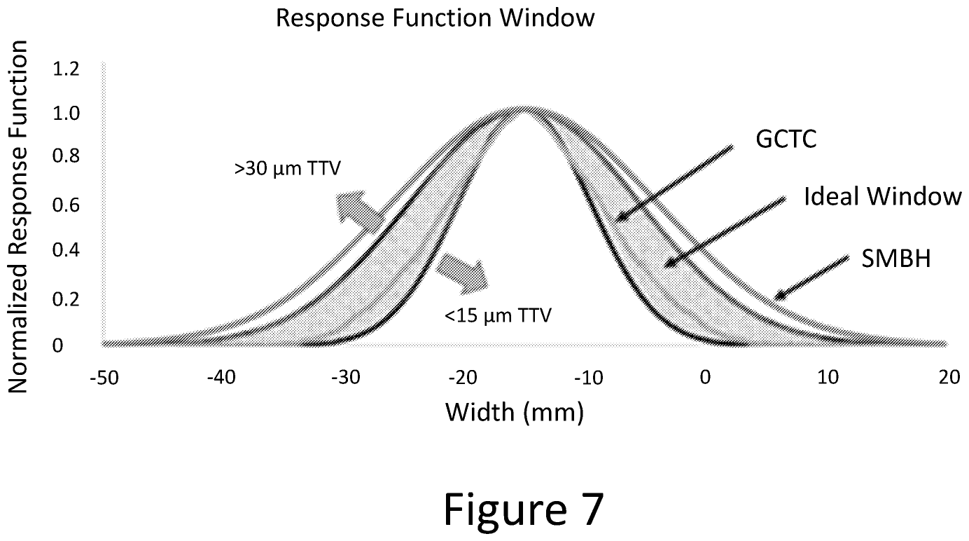

FIG. 7 shows exemplary performance of the SMBH illustrated in FIGS. 1A-1D against the GCTC. A curve illustrates what was achievable using the SMBH approach. The shaded area shows the window between acceptable thickening profiles that would allow total thickness variation (TTV) tuning between 15 microns and 30 microns. Another curve inside this window is actual experimental data from the GCTC (one single channel activated), showing initial results.

Dynamic feedback to the CTC and/or UMBH can be provided by measuring a thickness of the ribbon while it is in the melt or after it leaves the melt. This feedback can be performed to maintain the thickness profile over an extended length of the ribbon. One or more segments of the CTC and/or UMBH can be adjusted to produce a ribbon with a desired thickness or to compensate if the ribbon is not within specifications.

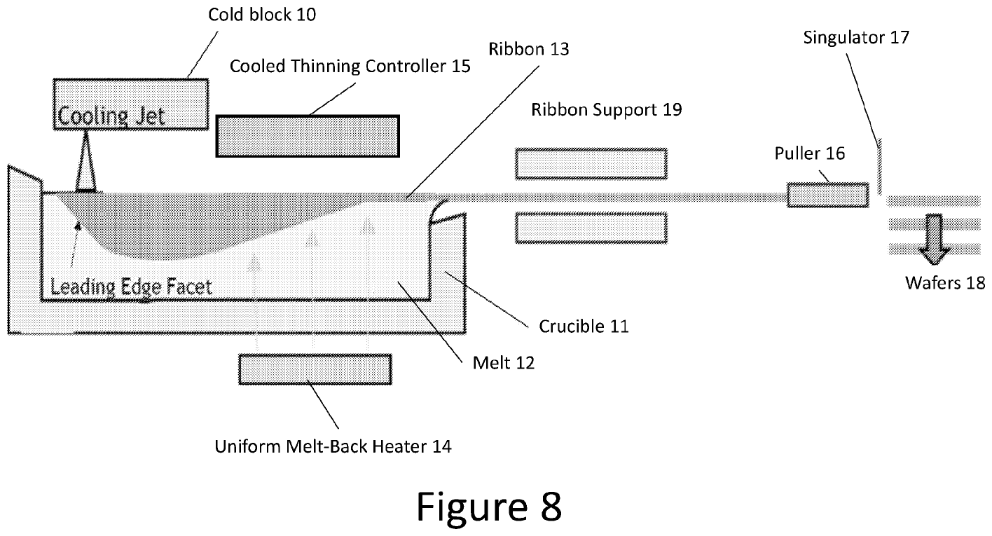

Embodiments of the cooled thinning controller and uniform melt-back heater disclosed herein can be used in an FSM system for ribbon production. A system for FSM ribbon production, such as that illustrated in FIG. 8, can include a crucible for housing a melt and a cold initializer having a cold initializer surface that directly faces an exposed surface of the melt. The cold initializer (e.g., a WCI) is configured to form a ribbon floating on the surface of the melt at the same rate it is pulled. During operation a melt is provided in the crucible. The thickness of the ribbon is controlled in a melt-back zone before the ribbon separates from the melt at the crucible wall where a stable meniscus forms. The crucible can include IDBs as illustrated in FIG. 2A or FIG. 5.

A system for wafer production, such as that illustrated in FIG. 8, can include a crucible 11 for housing a melt and a cold block 10 having a cold block surface that directly faces an exposed surface of the melt 12. The cold block 10 is an example of a cold initializer. The cold block 10 is configured to generate a cold block temperature at the cold block surface that is lower than a melt temperature of the melt 12 at the exposed surface whereby a ribbon 13 is formed on the melt. The cold block 10 also can provide a cooling jet to assist in formation or initialization of the solid ribbon 13. The cold block 10 can be water-cooled. During operation a melt 12 is provided in the crucible 11. A ribbon 13 is formed horizontally on the melt using the cold block 10 with a cold block surface that directly faces an exposed surface of the melt 12. A uniform melt-back heater 14 and cooled thinning controller 15 (e.g., a GCTC or RCTC) can adjust the thickness of the ribbon 13 in the melt after it is formed. The ribbon 13 is pulled from the melt 12 at a low angle off the melt surface using the puller 16, which may be a mechanical ribbon pulling system. The ribbon 13 may be pulled from the crucible 11 at a 0° angle or at a small angle relative to a surface of the melt 12 (e.g., less than 10°). The ribbon 13 is supported and singulated into wafers, such as using a singulator 17. The wafers 18 made using this system can have the thickness described herein.

The embodiments disclosed herein can control the ambient environment around the ribbon 13 at high temperatures (e.g., 1200 to 1414° C. or 1200 to 1400° C.). Relevant atmospheric pressures include low sub-atmospheric pressures (e.g., 0.01 atm) to positive-pressure systems (e.g., 5 atm). Further, the gas flow profiles around the ribbon surfaces can minimize metallic contamination via gas transport.

There can be one or more gas zones with different gas mixtures around the ribbon 13. These gas zones can target one or more sides of the ribbon 13. In an instance, the gas zones can be configured to minimize metallic contamination to the ribbon surface. The gas zones can be separated by structural barriers or gas barriers, which can isolate each gas zone.

The solid ribbon 13 can separate over the edge of the crucible 11 at a slightly raised height of approximately 0.2 mm to 2 mm, which can ensure that a stable meniscus is maintained and that the melt 12 does not spill over the lip of the crucible 11 during separation. The crucible 11 edge can also be shaped to include pinning features to increase meniscus or capillary stability. The gas pressure on the meniscus between the ribbon surface and the crucible 11 can be increased to increase meniscus stability. One example on how to increase gas pressure is to locally focus an impinging jet directly at this meniscus formed between the crucible edge and the ribbon surface.

As the ribbon 13 travels from the cold initializer to where it reaches room temperature, the ribbon 13 is mechanically supported to minimize metallic contamination and the generation of defects, such as with ribbon support 19. Mechanically deflecting a thin ribbon 13 at high temperature can mechanically yield (i.e. plastically deform) the ribbon 13 and give rise to undesirable crystal defects such as dislocations. Physical contact with the ribbon 13 can locally result in undesirable slip, dislocations, and metallic contamination. As the ribbon 13 floats on the melt surface, a mechanism to support the ribbon 13 over the melt is optional. The ribbon 13 can be supported as it separates over the edge of the crucible 11 because that is where it is expected to experience the most mechanical deflection. The ribbon 13 can be supported during the pulling after the ribbon 13 is separated from the melt via several approaches, including gas flow levitation and/or a mechanical support. First, the ribbon 13 can be levitated by directed gas flows that create local high or low pressures on the ribbon surface to support the ribbon 13. Examples of gas flow levitation approaches can include Bernoulli grippers, gas bearings, air-hockey tables, or other techniques that use gas pressure. Another approach is to mechanically support the ribbon 13 with, for example, rollers or sliding rails. To minimize deleterious effects with this contact approach, the contact pressure between these supports and the ribbon surface may be minimized. The supports may be made of high temperature semiconductor-grade materials that do not readily contaminate silicon like silicon carbide, silicon nitride, quartz, or silicon. Deflection of the ribbon 13 may be minimized to prevent the ribbon 13 from mechanically yielding, warping, or producing structural defects.

The system may include one or more temperature zones, which may be from 2 cm to 500 cm in length. More than two temperature zones are possible. Each of the zones can be separated or isolated. Gas curtains between the zones can provide isolation. Gas flows using particular pressures, gas flows combined with vacuum settings or vacuum pumps, baffles or other geometric structures, and/or the ribbon 13 itself also can be used to isolate the zones from each other. In an instance, the zones can be separated by insulation, heat shields, heaters, or other physical mechanisms.

For example, the temperature zones can be from 800° C. to approximately 1414° C. using either an inert or reducing atmosphere. The dwell time can be from 1 minute to 60 minutes per temperature zone. In an instance, the temperature in one zone can span the range from 1200° C. to approximately 1414° C. Additional gases, such as dopants, can be included at similar temperatures.

In an instance, there may be sections where temperature is maintained at a temperature setpoint for a particular time to control defect profiles. A temperature gradient across the ribbon 13 can be implemented to minimize the effects of thermal stress. The temperature gradient along the pull direction can be implemented to minimize the effects of thermal stress. The second derivative of the temperature profile can be controlled to minimize thermal stress and mechanical warpage. The system can include one or more temperature gradients and/or second derivatives. The temperature zones can be created and maintained by a combination of resistive heaters, profiled insulation, radiative geometries and/or surfaces, and gas flows.

In combination with the tailored thermal profile, the gas atmosphere and mechanical support of the ribbon 13 can be tailored to also increase material performance as the ribbon 13 transitions from high temperature to room temperature. The ribbon 13 can be exposed to different gas mixtures to either create functionality or increase performance. Exposing the ribbon 13 to an inert gas like argon or nitrogen can maintain its cleanliness, and creating a mixture of argon with a reducing gas like hydrogen can further assist the surface cleanliness. In addition, it has been shown that mixtures of argon, nitrogen, and oxygen can increase the precipitation of oxides if that is desired. Using a gas mixture containing oxygen and some water vapor can grow a thermal oxide on the wafer surface that minimizes metallic contamination. Another gas mixture can contain phosphorous oxychloride or a chloride gas. Exposing the ribbon to phosphorous oxychloride or chloride gas would have the combined effect of locally creating a wafer surface with a high phosphorous concentration and a protective glass surface. This highly doped surface would getter metallic contamination, and therefore increase bulk MCL which would be desirable for devices like solar cells. The glass surface would prevent further metallic contamination from the environment to the wafer. While the ribbon 13 travels from the crucible to room temperature, there can be one or many gas mixtures exposed to the ribbon. These gas mixtures can be separated by gas curtains, guiding flow geometries, and other techniques intended to separate gas mixtures from each other. Atmospheric pressures in one or all of these gas zones can include low sub-atmospheric pressures (e.g., 0.01 atm) to positive-pressure systems (e.g., 5 atm). The system atmosphere can be open to the ambient environment or sealed. The gas flow profiles around the ribbon surfaces can be tailored to increase outgassing while also minimizing metallic contamination via gas transport.

After the ribbon 13 is cooled to approximately room temperature, the ribbon 13 can be singulated into discrete wafers 18. The wafers 18 can be rectangular, square, pseudo square, circular, or any geometry that can be cut from a ribbon. Singulation can be performed by traditional techniques like laser scribing and cleaving, laser ablation, and mechanical scribing and cleaving. The final discrete wafer lateral dimensions can range from 1 cm to 50 cm (e.g., 1-45 cm or 20-50 cm), with thickness from 50 microns to 5 mm and either a uniform thickness (low TTV), or even a tailored thickness gradient, if that were desirable.

The wafers 18 can then be further processed or marked to generate additional features or material properties for the final semiconductor devices or solar cells. In an example, the wafers 18 can be ground, polished, thinned or textured with chemicals or mechanical abrasion. In another example, the wafers 18 can be either chemically textured or mechanically polished to create the desired final surface roughness. Material or geometry features can be added to the surface or in the bulk create the final desired devices. Example final products can include but are not limited to solar cells, MOSFETs, or anodes for lithium-ion batteries.

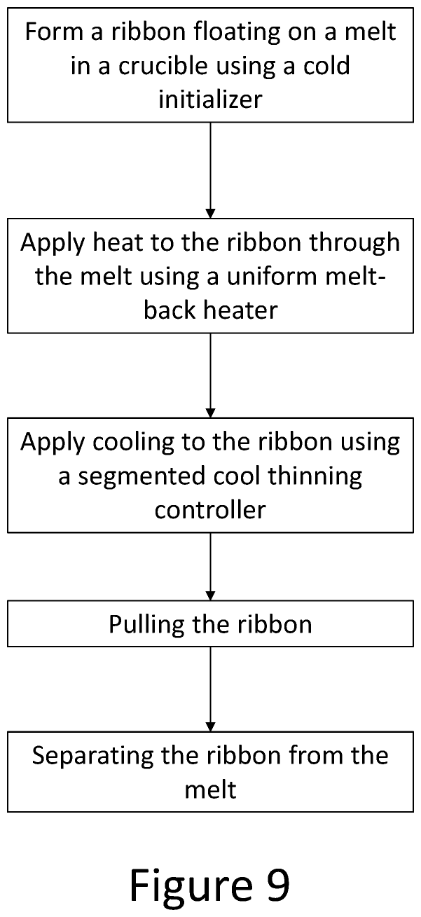

FIG. 9 is a flowchart of an exemplary embodiment. A melt is provided in a crucible, which may include silicon. A ribbon is formed floating on the melt using a cold initializer facing an exposed surface of the melt. The ribbon is single crystal. Heat is applied to the ribbon through the melt using a uniform melt-back heater disposed below the melt. Diffusion of heat into an edge of the ribbon can be minimized using two IDBS disposed in the melt. Cooling is applied to the ribbon using a segmented cooled thinning controller facing the crystalline ribbon above the melt. The segments of the cooled thinning controller and/or the uniform melt-back heater can be adjusted to provide a uniform thickness of the crystalline ribbon. The ribbon is pulled such that the ribbon is formed at a same rate as the pulling. The ribbon is separated from a wall of a crucible where a stable meniscus forms.

The cooled thinning controller can include a plurality of gas jets or can include a cold block and a plurality of heaters.

Embodiments disclosed herein can include a processor that controls the various components of the system, such as the UMBH and/or the CTC. In some embodiments, various steps, functions, and/or operations of system and the methods disclosed herein are carried out by one or more of the following: electronic circuits, logic gates, multiplexers, programmable logic devices, ASICs, analog or digital controls/switches, microcontrollers, or computing systems. Program instructions implementing methods such as those described herein may be transmitted over or stored on carrier medium. The carrier medium may include a storage medium such as a read-only memory, a random-access memory, a magnetic or optical disk, a non-volatile memory, a solid state memory, a magnetic tape, and the like. A carrier medium may include a transmission medium such as a wire, cable, or wireless transmission link. For instance, the various steps described throughout the present disclosure may be carried out by a single processor (or computer system) or, alternatively, multiple processors (or multiple computer systems). Moreover, different sub-systems of the system may include one or more computing or logic systems. Therefore, the above description should not be interpreted as a limitation on the present disclosure but merely an illustration.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. An apparatus for controlling a thickness of a crystalline ribbon grown on a surface of a melt comprising:
a crucible configured to hold a melt;
a cold initializer facing an exposed surface of the melt;
a segmented cooled thinning controller disposed above the crucible on a side of the crucible with the cold initializer, wherein the segmented cooled thinning controller is configured to cool a surface of the melt; and
a uniform melt-back heater disposed below of the crucible opposite the cooled thinning controller, wherein the uniform melt-back heater is configured to uniform heat to the melt.

2. The apparatus of claim 1, further comprising two insulating diffusion barriers disposed on the crucible between the cool thinning controller and the uniform melt-back heater, wherein the insulating diffusion barriers are disposed in the melt on opposite sides of a ribbon formed on the melt.

3. The apparatus of claim 1, wherein the cooled thinning controller includes a plurality of gas jets.

4. The apparatus of claim 1, wherein the cooled thinning controller includes a cold block and a plurality of heaters.

5. The apparatus of claim 4, wherein the cooled thinning controller includes one or more heat shields between the heaters.

6. The apparatus of claim 1, wherein the crucible has a depth of 0.5 cm or more.

7. The apparatus of claim 1, further comprising a puller configured to pull a ribbon formed on a surface of the melt in the crucible.

8. The apparatus of claim 1, further comprising an insulating diffusion barrier disposed on the crucible between the cold initializer and the cooled thinning controller.

9. A method comprising:
providing a melt in a crucible;
forming a ribbon floating on the melt using a cold initializer facing an exposed surface of the melt, wherein the ribbon is single crystal;
applying heat to the ribbon through the melt using a uniform melt-back heater disposed below the melt;
applying cooling to the ribbon using a segmented cooled thinning controller facing the crystalline ribbon above the melt;
pulling the ribbon, wherein the ribbon is formed at a same rate as the pulling; and
separating the ribbon from the melt at a wall of the crucible where a stable meniscus forms.

10. The method of claim 9, further comprising minimizing diffusion of heat into an edge of the ribbon using two insulating diffusion barriers disposed in the melt.

11. The method of claim 9, wherein the segmented cooled thinning controller includes a plurality of gas jets.

12. The method of claim 9, wherein the segmented cooled thinning controller includes a cold block and a plurality of heaters.

13. The method of claim 9, further comprising adjusting the segmented cooled thinning controller and/or the uniform melt-back heater to provide a targeted thickness profile to the ribbon.

14. The method of claim 13, further comprising measuring a thickness of the ribbon and providing dynamic feedback control of channels in the segmented cooled thinning controller to maintain the thickness profile over an extended length of the ribbon.

15. The method of claim 9, wherein the melt includes silicon.
